(19) United States
(12) Patent Application Publication
(10) Pub. No.: US 2019/0297923 A1
(43) Pub. Date: Oct. 3, 2019

(54) INDUCTION HEATING AND COOKING

(71) Applicant: Lee Huang, Palo Alto, CA (US)

(72) Inventor: Lee Huang, Palo Alto, CA (US)

(21) Appl. No.: 15/942,528

(22) Filed: Apr. 1, 2018

(51) Int. Cl. A23L 5/30; H05K 7/20; H05B 6/06; H05B 6/12; B05D 3/00

(52) U.S. Cl. CPC A23L 5/30; H05K 7/2039; H05K 9/00; H05B 6/1245; B05D 3/207; H05B 6/062

(57) ABSTRACT

A cooktop heating element includes a helix shaped induction coil. The helix shaped induction coil includes a first array of parallel current-carrying wires and a second array of return current carrying wires. A magnetic shielding sheet is placed between the first array of parallel current-carrying wires and the second array of return current carrying wires. The magnetic shield sheet magnetically shields the first array of parallel current-carrying wires from the second array of return current carrying wires.

### BACKGROUND

Energy efficient appliances improve the energy efficiency in kitchens. Commercial kitchens and restaurants use gas for cooking because gas cooking tends to more efficient than use of electrical appliances for cooking. In recent years, induction cooking has received some traction, especially in hotels and airport facilities that require use of electricity to cook.

The heating element used for induction heating is a conductive coil. Current through the coil produces an oscillating magnetic field. The magnetic field is created along the axial direction of the coil. Cookware, such as a stainless steel or iron pot, or a stainless steel or iron pan, is placed in the center of the coil, oriented axially. The oscillating magnetic field produced by the coil induces eddy current within conductive material within the cookware. Due to the electrical resistance within the cookware, the induced currents will generate heat in the cookware, thereby heating up the cookware.

Induction coils are designed in a plane, typically in a donut shape, so that the magnetic field can be spread out to the bottom of the pot. Because of the donut shape, the heating area is in an annular shape leaving a cold region at the center. Currently, this effect is mitigated by using a composite base for cookware, for example, sandwiching an aluminum disc between layers of ferromagnetic material to spread the heat across the base of the cookware.

### BRIEF DESCRIPTION OF THE DRAWINGS

FIG. 1 shows an induction heating coil with a work piece in accordance with the prior art.

FIG. 2 shows a conventional induction cooking coil for a cooktop in accordance with the prior art.

FIG. 3 shows a conventional induction cooking coil used with cookware in accordance with the prior art.

FIG. 4 shows a linear current wire array and a return current array in accordance with an implementation.

FIG. 5 shows a linear current wire array with a magnetic shield sheet in accordance with an implementation.

FIG. 6 shows a circular induction wire array and a cookware in accordance with an implementation.

FIG. 7 shows a hexagonal induction wire array in accordance with an implementation.

FIG. 8 shows a circular induction wire array and a wok in accordance with an implementation.

### DESCRIPTION OF THE EMBODIMENTS

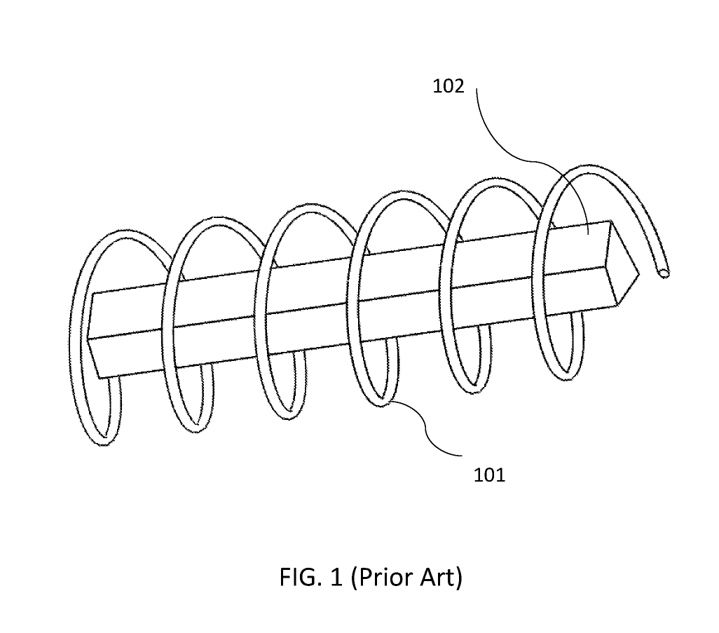

A typical induction heater set up is shown in FIG.1 where current runs through an electrical coil 101, causing a magnetic field to be uniformly generated in the cylindrical space inside the coil along the axis of the coil. When the current is an alternating current, the magnetic field is time-varying. A workpiece 102 is composed of magnetic material, such as metal with iron content. When workpiece 102 is placed inside electrical coil 101, the time-varying magnetic field will generate eddy currents through the work piece. The eddy currents generate heat within the work piece.

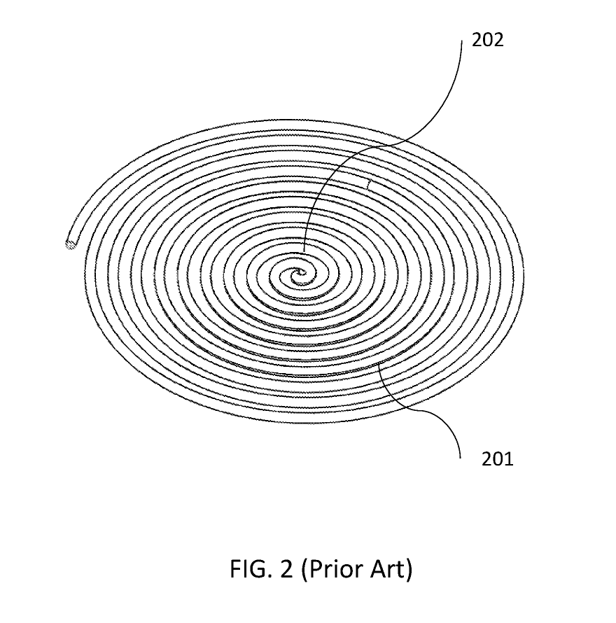

For an induction stove, the coil is arranged differently than a typical induction heater. The typical design of an induction stove coil 201 is shown in FIG.2, where induction stove coil 201 is wound on a flat surface in a disc shape or donut shape. This shape allows induction stove coil 201 to induce eddy currents along a larger area. In this configuration, induction stove coil 201 creates magnetic field that is typically strong in the area where the wires of induction stove coil 201 are parallel, such as in area away from the center of induction stove coil 201 where the magnetic field from nearby currents are constructively superimposed. The magnetic field in a central area 202 of induction stove coil 201, where the nearby currents are opposing, is the weakest. As a result, a typical heating profile of an induction cooktop is annular. Such a pattern is inconvenient when cooking, as it is preferred to have an even heating surface. Hot spots can cause uneven cooking.

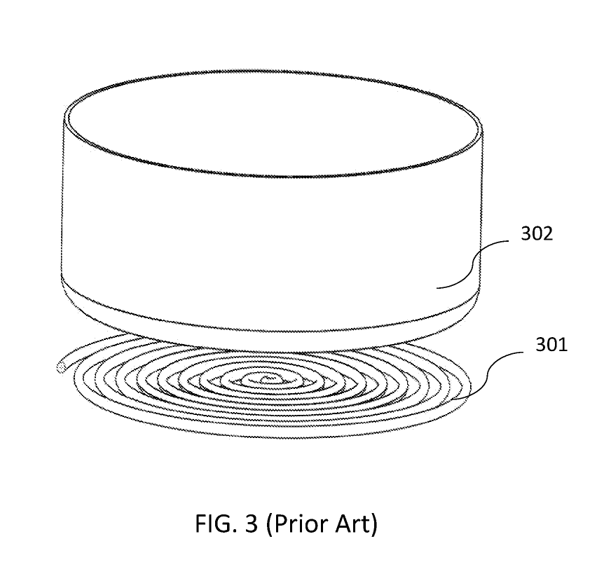

FIG.3. shows induction ready cookware 302 placed on one side of a disc-shaped induction stove coil 301. In order to overcome the annular heating profile produced by a disc-shaped induction stove coil 301 cookware 302 can be produced in a multi-ply implementation of clad metal where, for example, a layer of aluminum is sandwiched between two sheets of stainless steel. The highly thermally conductive aluminum layer transfers heat laterally along sheets of stainless steel to evenly distribute the heat. For more even heating, a greater number of layers are used, such as a 5-ply system: steel-aluminum-steel-aluminum-steel. The uneven heating from induction is somewhat improved by these material systems. However, these material systems tend to be expensive and limited in area.

Using a disc-shaped induction stove coil induction coil, it is difficult to create a large uniform heating area such as is needed for griddle cooking. Further, using a composite metal plate to even out the temperature across the large area required by a griddle can be expensive.

However, as described below, it is possible to design an induction heating element that will eliminates temperature hot spots and provides an even heating surface for both industrial and foodservice applications. This is done, for example, by providing a first array of parallel current-carrying wires, oriented in the same direction and sufficiently closely spaced such that the wires effectively create a flat current sheet. Current through the flat current sheet induces a uniform magnetic field above the wire array. In order to form a closed circuit, there is a second array of return current carrying wires arranged under the first array of parallel current-carrying wires. Magnetic field shielding is placed between the first array of parallel current-carrying wires and the second array of return current carrying wires so that the magnetic field of the second array of return current carrying wires does not cancel out the magnetic field of the first array of parallel current-carrying wires. The result is a strong uniform magnetic field above the first array of parallel current-carrying wires, where cookware such as a griddle can be placed to be heat up uniformly.

Although the following detailed description contains many specifics for the purpose of illustration, anyone of ordinary skill in the art will readily appreciate that many variations and alterations to the following exemplary details may be made. One skilled in the relevant art will recognize, however, that the concepts and techniques disclosed herein can be practiced without one or more of the specific details, or in combination with other components, etc. In other instances, well-known implementations or operations are not shown or described in detail to avoid obscuring aspects of various examples disclosed herein.

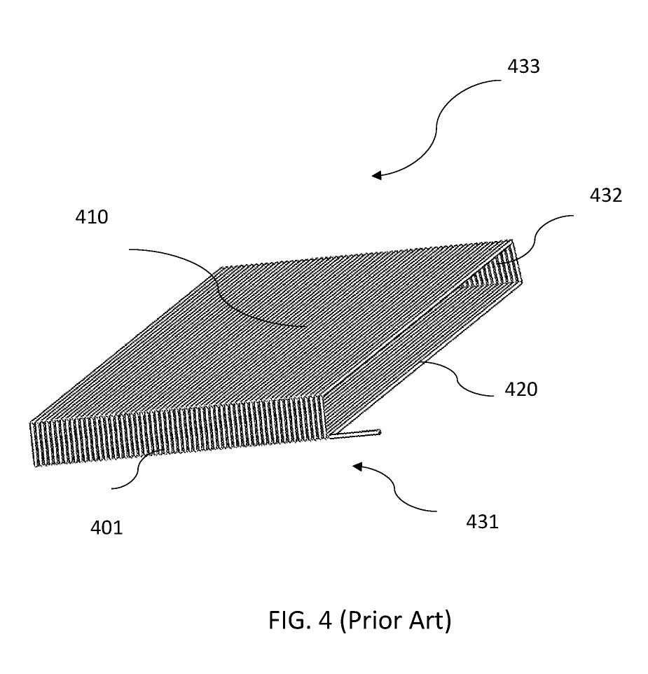

FIG. 4 shows electric induction wire 401 forming a helix shaped induction coil. In FIG. 4, electric induction wire 401 is arranged as a rectangular helix. The helix includes a first array of parallel current-carrying wires 410 and a second array of return current carrying wires 420. For the configuration of electric induction wire 401 shown in FIG. 4, when an electric current is running through electric induction wire 401, a magnetic field is generated and mainly distributed in a space 432 between first array of parallel current-carrying wires 410 and second array of return current carrying wires 420. The magnitude of the magnetic field is the sum of the magnetic field contributed from current in parallel current-carrying wires 410 and the current in second array of return current carrying wires 420.

The magnetic field generated in area 431 below second array of return current carrying wires 420 and in area 432 above first array of parallel current-carrying wires 410 is negligible because in these areas the magnetic effects of second array of return current carrying wires 420 and first array of parallel current-carrying wires 410 tend to cancel out.

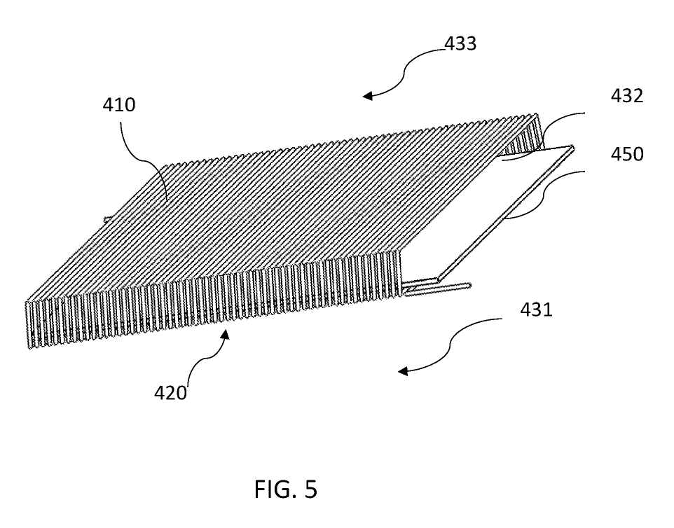

FIG.5. shows a magnetic shielding sheet 450 between first array of parallel current-carrying wires 410 and second array of return current carrying wires 420. First array of parallel current-carrying wires 420 is composed of wires oriented in the same direction and sufficiently closely spaced such that the wires effectively create a current sheet.

The purpose of magnetic shielding sheet 450 is to separate the magnetic field generated from current through first array of parallel current-carrying wires 410 from the magnetic field generated from current through first array of parallel current-carrying wires 410 from second array of return current carrying wires 420. Magnetic shielding sheet 450 significantly reduces or eliminates the magnetic field cancellation that resulted in a negligible magnetic field in area 431 below second array of return current carrying wires 420 and in area 432 above first array of parallel current-carrying wires 410. When magnetic shielding sheet 450 is inserted between first array of parallel current-carrying wires 410 and second array of return current carrying wires 420, induction ready cookware placed in area 431 below second array of return current carrying wires 420 and in area 432 above first array of parallel current-carrying wires 410 will receive sufficient magnetic energy for cooking. For example, magnetic shielding sheet 450 contains a heat sink for heat dissipation.

For example, magnetic shielding sheet 450 has the properties of high saturation level and low eddy current density, leading to low power loss. With the combination of the thickness of the material and the saturation of magnetic shielding sheet 450, the magnetic field in space 432 generated from current in first array of parallel current-carrying wires 410 will not be affected much by the magnetic field generated from current in second array of return current carrying wires 420. If the magnetic field in space 432 is intended for induction cooking, it is preferable that magnetic shielding sheet 450 should be placed close to second array of return current carrying wires 420. The magnetic flux conductivity of magnetic shielding sheet 450 should match the total magnetic field flux generated from total electric current from second array of return current carrying wires 420. In this way the magnetic field distribution from current in the first array of parallel current-carrying wires 410 should be minimally affected by this shielding sheet.

Alternatively, two sheets of magnetic shielding can be used, one close to first array of parallel current-carrying wires 410 and one close to second array of return current carrying wires 420, so that the magnetic field can be concentrated near first array of parallel current-carrying wires 410 and near second array of return current carrying wires 420. Nevertheless, to minimize loss it is preferable to use a single sheet to redirect the magnetic field from second array of return current carrying wires 420.

An important property of magnetic shielding sheet 450 is low loss, so that loss resulting from the presence of magnetic shielding sheet 450 does not affect the overall efficiency of the induction equipment. The loss in magnetic shielding sheet 450 includes hysteresis losses and eddy current losses. The hysteresis loss is due to the flipping of the domains of magnetic shielding sheet 450, which causes energy to be lost as heat. With proper selection of the material used to produce magnetic shielding sheet 450, it is possible to design an induction cooking appliance with minimum loss due to magnetic shielding sheet 450. If necessary, second array of return current carrying wires 420 and magnetic shielding sheet 450 can be mounted on a heat sink that dissipates the heat generated from resistive losses in electric induction wire 401 and the heat generated from the eddy current and hysteresis losses in magnetic shielding sheet 450.

In FIG. 5, the induction coil pattern of electric induction wire 401 is rectangular, forming a module unit that can be arrayed to provide induction cooking for a large area. In additional to rectangular units, it is possible to cover large areas using hexagonal units or a combination of other geographic shapes such as hexagonal, round, oval square or other geographic shapes. An induction coil pattern of electric induction wire can form a helix pattern that produces a first array of parallel current-carrying wires with any desired geometry suitable for induction heating.

For example, a first array of parallel current-carrying wires can have a geometry suitable for even heating of a griddle cooking appliance. A typical griddle has a rectangular surface area such as twenty-four inches by twenty-four inches, or forty-eight inches by forty-eight inches. An array of induction cooking elements such as first array of parallel current-carrying wires 410 can be used to cover an entire griddle, resulting in a griddle appliance with uniform heating without the need for multi-ply surfaces. This is helpful as for a large griddle implemented using a tri-ply construction of the griddle surface, the layers tend to be thin, and this tends to warping in a griddle application. Using explosion bonding to obtain thicker multi-ply composite metal constructions is expensive.

A typical griddle plate is a one-half inch to one-inch thick steel plate. When using first array of parallel current-carrying wires 410 or a similar uniform heating wiring array, it is possible to use a thinner griddle plate because with the uniform heating provided by first array of parallel current-carrying wires 410, the chance of warping is reduced.

For example, first array of parallel current-carrying wires 410 is used to implement one modular element in an array of modular elements. In such an array, it is preferable to be able to control the induction power to each individual modular element. When a temperature sensor is installed in each modular element to sense the temperature of the cookware at the area of the modular element, it is possible to provide power to each modular element accordingly. For example, when a cold piece of meat is place in area of a griddle, the local temperature of the griddle metal plate will drop. The dropping of the temperature locally can contribute to warping of the metal plate. Therefore, it is desirable to for a griddle plate to increase the power to a modular element that heats that cold area, without increasing the temperature of other areas of griddle plate not loaded with cold meat. Such individual control of the modular elements improves overall energy efficiency of griddle cooking.

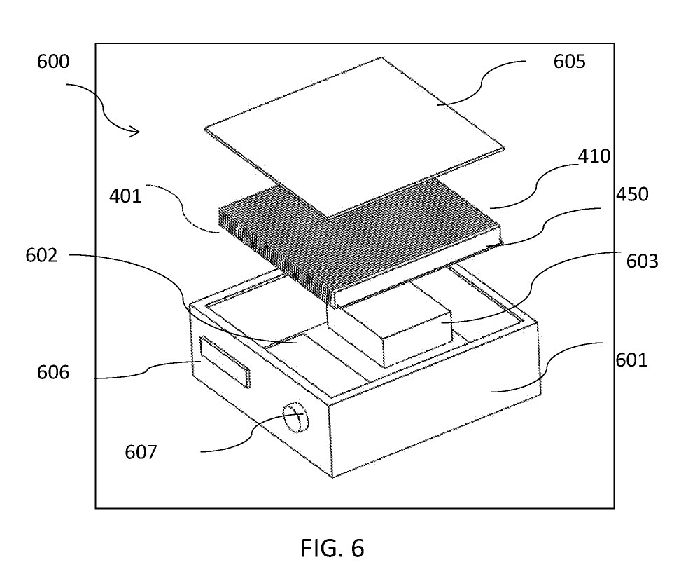

FIG. 6 shows a cooktop assembly 600 that includes a case 601 made, for example, of stainless steel. A circuit board 602 and a power supply 603 are within case 601. Helix-shaped electric induction wire 401 is placed so that first array of parallel current-carrying wires 410 is under a cooking griddle plate 605. Magnetic shielding sheet 450 is within helix-shaped electric induction wire 401 under first array of parallel current-carrying wires 410. In operation, the power level and the temperature of the steel plate 605 will be showed on a display 606 and can be controlled by turning a dial 606. Temperature of griddle plate 605 will be uniform which is ensured by the uniform wiring format of first array of parallel current-carrying wires 410. The size of case 601 and griddle plate 605 can be made to be a multiple of the size of first array of parallel current-carrying wires 410 in length and in width. In this case, multiple modular elements, each with its own array of parallel current-carrying wires is used to heat the large area griddle with uniform temperature with the ability of individually control current to each of the multiple modular elements to handle situations when food load is in some portion of the griddle area.

In addition to cooking, another application of induction heating can be for heating up sheet metal after painting to help the paint set. Using induction to induce eddy currents within the sheet metal can lead to better finish quality than is provided by heating the paint using a heat lamp. Also, providing heat via induction to the sheet metal helps strengthen the bond between paint and metal.

In wok cooking, it is vital that the center of the wok is hot. This is the opposite to the donut pattern resulting from conventional induction stoves. This makes it challenging for chefs to use induction heating when cooking with a wok. Some chefs adapt to induction wok cooking by scooping oil from the center area to the ring area to heat up the oil quicker.

As described above using a first array of parallel current-carrying wires created from a helix-shaped induction coil wired as described above can provide for induction heating where a heated central area is the hot area for cooking, as is provided by a conventional gas burner wok range.

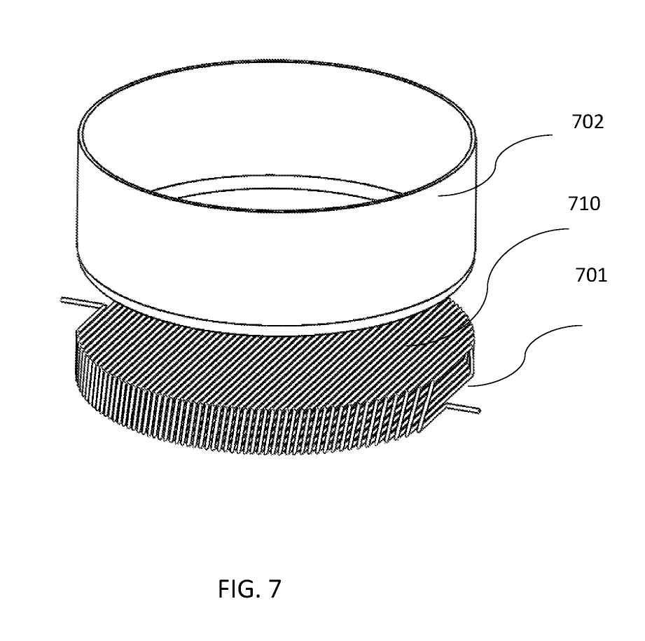

For example, FIG. 7 shows electric induction wire 701 patterned in a circular design to provide a first array of parallel current-carrying wires 710 for heating. Alternatively, a hexagonal pattern or a pattern of another geographic shape can be used for a cooktop assembly.

First array of parallel current-carrying wires 710 provides a uniform heating pattern that provides heat in the center area of a burner. When cookware 702 is placed closed to first array of parallel current-carrying wires 710 heating is uniform across the bottom of cookware 702.

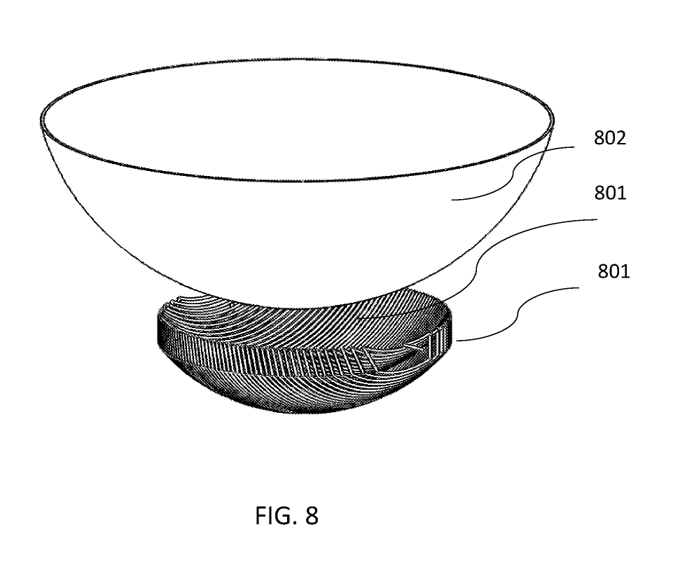

FIG.8 shows how electric induction wire 801 is patterned in a circular design optimal for heating a wok. First array of parallel current-carrying wires 810 forms a concave top surface where the center portion of first array of parallel current-carrying wires 810 is recessed to conform the shape of first array of parallel current-carrying wires 810 to the bottom curvature of a wok 802. This eliminates the cold spot that results from use of conventional inductive elements. To further optimize first array of parallel current-carrying wires 810 for cooking with a wok, the parallel line pattern of first array of parallel current-carrying wires 810 can be shaped in an hour glass pattern where wires in the middle area have closer wire spacing. The closer wire spacing increases the magnetic field intensity in the middle area and thus increases heating generated at the center of the wok. This concentration of heating in the center of the wok mimics the hot center area in the conventional gas cooking wok range.

While in the examples above, electric induction wires are arranged so that the resulting first array of parallel current-carrying wires is arranged as a single layer. However, multilayer current coils can be used to increase the strength of the induction magnetic field and therefore increasing the power delivered for heating.

The foregoing discussion discloses and describes merely exemplary methods and implementations. As will be understood by those familiar with the art, the disclosed subject matter may be embodied in other specific forms without departing from the spirit or characteristics thereof. Accordingly, the present disclosure is intended to be illustrative, but not limiting, of the scope, which is set forth in the following claims.

What is claimed is:

1. A cooktop assembly comprising:
a cooktop heating element including:
a helix shaped induction coil, the helix shaped induction coil including:
a first array of parallel current-carrying wires oriented in a same direction and sufficiently closely spaced such that the wires effectively create a current sheet, and
a second array of return current carrying wires, and
a magnetic shielding sheet placed between the first array of parallel current-carrying wires and the second array of return current carrying wires, the magnetic shield sheet magnetically shielding the first array of parallel current-carrying wires from the second array of return current carrying wires.

2. A cooktop assembly as in claim 1, wherein the first array of parallel current-carrying wires has a rectangular shape.

3. A cooktop assembly as in claim 1, wherein the first array of parallel current-carrying wires has a substantially round shape.

4. A cooktop assembly as in claim 1, wherein the first array of parallel current-carrying wires has a hexagonal shape.

5. A cooktop assembly as in claim 1, wherein the first array of parallel current-carrying wires forms a concave surface.

6. A cooktop assembly as in claim 1, wherein the first array of parallel current-carrying wires forms a substantially flat surface.

7. A cooktop assembly as in claim 1, wherein the first array of parallel current-carrying wires includes wires that are substantially equal distance from each other.

8. A cooktop assembly as in claim 1, wherein the first array of parallel current-carrying wires includes wires that vary in distance from each other.

9. A cooktop assembly as in claim 1, wherein the first array of parallel current-carrying wires includes multiple layers of wires.

10. A cooktop heating element comprising:
a helix shaped induction coil, the helix shaped induction coil including:
a first array of parallel current-carrying wires oriented in a same direction and sufficiently closely spaced such that the wires effectively create a current sheet, and
a second array of return current carrying wires; and
a magnetic shielding sheet placed between the first array of parallel current-carrying wires and the second array of return current carrying wires, the magnetic shield sheet magnetically shielding the first array of parallel current-carrying wires from the second array of return current carrying wires.

11. A cooktop heating element as in claim 10, wherein the first array of parallel current-carrying wires has a rectangular shape, a substantially round shape or a hexagonal shape.

12. A cooktop heating element as in claim 10, wherein the first array of parallel current-carrying wires forms a concave surface.

13. A cooktop heating element as in claim 10, wherein the magnetic shielding sheet includes a heat sink for heat dissipation.

14. A cooktop heating element as in claim 10, wherein the first array of parallel current-carrying wires includes wires that vary in distance from each other.

15. A cooktop heating element as in claim 10, wherein the first array of parallel current-carrying wires includes multiple layers of wires.

16. A method for drying paint on sheet metal, the method comprising:
magnetically inducing eddy currents through the sheet metal using an inductive heating element, wherein the inductive heating element is formed from a helix shaped induction coil, the helix shaped induction coil including:
a first array of parallel current-carrying wires oriented in the same direction and sufficiently closely spaced such that the wires effectively create a current sheet, and
a second array of return current carrying wires; and
using a magnetic shielding sheet placed between the first array of parallel current-carrying wires and the second array of return current carrying wires to magnetically shield the first array of parallel current-carrying wires from the second array of return current carrying wires.

17. A method as in claim 16, wherein the first array of parallel current-carrying wires has a rectangular shape, a substantially round shape or a hexagonal shape.

18. A method as in claim 16, wherein the first array of parallel current-carrying wires forms a concave surface.

19. A method as in claim 16, wherein the first array of parallel current-carrying wires forms a substantially flat surface.

20. A method as in claim 16, wherein the magnetic shielding sheet includes a heat sink for heat dissipation.
